(19) United States
(12) Patent Application Publication
(10) Pub. No.: US 2016/0043178 A1
(43) Pub. Date: Feb. 11, 2016

(54) SEMICONDUCTOR COMPONENT AND METHOD OF MANUFACTURE

(71) Applicant: Semiconductor Components Industries, LLC, Phoenix, AZ (US)

(72) Inventors: Chun-Li Liu, Scottsdale, AZ (US); Ali Salih, Phoenix, AZ (US)

(21) Appl. No.: 14/452,130

(22) Filed: Aug. 5, 2014

(51) Int. Cl. H01L 29/10; C30B 23/02; C30B 19/12; H01L 21/02; H01L 29/20; H01L 29/201; H01L 29/207; H01L 29/205; C30B 25/18; C30B 29/40

(52) U.S. Cl. CPC H01L 29/1054; C30B 25/183; C30B 23/025; C30B 19/12; C30B 29/406; H01L 29/2003; H01L 29/201; H01L 29/207; H01L 29/205; H01L 21/02381; H01L 21/02458; H01L 21/0254

(57) ABSTRACT

In accordance with an embodiment, a method for manufacturing a semiconductor component includes providing a semiconductor material having a surface, forming an epitaxial layer of carbon doped semiconductor material on the semiconductor substrate, the epitaxial layer having a surface, forming a nucleation layer on the epitaxial layer; and forming a layer of III-nitride material on the nucleation layer. In accordance with another embodiment, the semiconductor component includes a silicon semiconductor substrate of a first conductivity type; a carbon doped epitaxial layer on the silicon semiconductor substrate; a buffer layer over the carbon doped buffer layer; and a channel layer on the buffer layer.

### TECHNICAL FIELD

The present invention relates, in general, to electronics and, more particularly, to semiconductor structures thereof, and methods of forming semiconductor devices.

### BACKGROUND

In the past, the semiconductor industry used various different device structures and methods to form semiconductor devices such as, for example, diodes, Schottky diodes, Field Effect Transistors (FETs), High Electron Mobility Transistors (HEMTs), etc. Devices such as diodes, Schottky diodes, and FETs were typically manufactured from a silicon substrate. Drawbacks with silicon based semiconductor devices include low breakdown voltages, excessive reverse leakage current, large forward voltage drops, unsuitably low switching characteristics, high power densities, and high costs of manufacture. To overcome these drawbacks, semiconductor manufacturers have turned to manufacturing semiconductor devices from compound semiconductor substrates such as, for example, III-N semiconductor substrates, III-V semiconductor substrates, II-VI semiconductor substrates, etc. Although these substrates have improved device performance, they are fragile and add to manufacturing costs. Thus, the semiconductor industry has begun using compound semiconductor substrates that are a combination of silicon and III-N materials to address the issues of cost, manufacturability, and fragility. A drawback with substrates that include silicon and a III-N material is the formation of an inversion layer at the interface between the silicon and the III-N material that increases the leakage current and limits the breakdown voltage. In addition, III-N films formed on a silicon wafer are brittle and highly stressed, which complicates wafer handling, processing, and packaging. III-N films formed on a silicon wafer also have lattice mismatches that cause a high edge and screw dislocation density and a high difference in their coefficients of thermal expansion. A III-N compound semiconductor material formed on silicon or other semiconductor substrate has been described in U.S. Patent Application Publication Number 2011/0133251 A1 by Zhi He and published on Jun. 9, 2011 and in U.S. Patent Application Publication Number 2013/0069208 A1 by Michael A. Briere and published on Mar. 21, 2013.

Accordingly, it would be advantageous to have a structure and method for manufacturing a semiconductor component using a semiconductor substrate that addresses the performance specifications and manufacturability. It would be of further advantage for the structure and method to be cost efficient to implement.

### BRIEF DESCRIPTION OF THE DRAWINGS

The present invention will be better understood from a reading of the following detailed description, taken in conjunction with the accompanying drawing figures, in which like reference characters designate like elements and in which:

FIG. 1 is a cross-sectional view of a semiconductor component during manufacture in accordance with an embodiment of the present invention;

FIG. 2 is a graph of a carbon doping profile in a silicon substrate in accordance with an embodiment of the present invention;

FIG. 3 is a cross-sectional view of another semiconductor component during manufacture in accordance with an embodiment of the present invention;

FIG. 4 is a graph of a carbon doping profile in a silicon substrate in accordance with an embodiment of the present invention;

FIG. 5 is a cross-sectional view of a semiconductor component during manufacture in accordance with another embodiment of the present invention;

FIG. 6 is a graph of a carbon doping profile in a silicon substrate in accordance with an embodiment of the present invention;

FIG. 7 is a cross-sectional view of a semiconductor component during manufacture in accordance with another embodiment of the present invention;

FIG. 8 is a graph of a carbon doping profile in a silicon substrate in accordance with an embodiment of the present invention;

FIG. 9 is a cross-sectional view of a semiconductor component during manufacture in accordance with another embodiment of the present invention;

FIG. 10 is a graph of a carbon doping profile in a silicon substrate and a material disposed on the silicon substrate in accordance with an embodiment of the present invention;

FIG. 11 is a cross-sectional view of a semiconductor component during manufacture in accordance with another embodiment of the present invention;

FIG. 12 is a graph of a carbon doping profile in a silicon substrate and a material disposed on the silicon substrate in accordance with an embodiment of the present invention;

FIG. 13 is a cross-sectional view of a semiconductor component during manufacture in accordance with another embodiment of the present invention;

FIG. 14 is a graph of a carbon doping profile in a silicon substrate and a material disposed on the silicon substrate in accordance with an embodiment of the present invention;

FIG. 15 is a cross-sectional view of a semiconductor component during manufacture in accordance with another embodiment of the present invention; and

FIG. 16 is a graph of a carbon doping profile in a silicon substrate and a material disposed on the silicon substrate in accordance with an embodiment of the present invention.

For simplicity and clarity of illustration, elements in the figures are not necessarily to scale, and the same reference characters in different figures denote the same elements. Additionally, descriptions and details of well-known steps and elements are omitted for simplicity of the description. As used herein current carrying electrode means an element of a device that carries current through the device such as a source or a drain of an MOS transistor or an emitter or a collector of a bipolar transistor or a cathode or anode of a diode, and a control electrode means an element of the device that controls current flow through the device such as a gate of an MOS transistor or a base of a bipolar transistor. Although the devices are explained herein as certain n-channel or p-channel devices, or certain n-type or p-type doped regions, a person of ordinary skill in the art will appreciate that complementary devices are also possible in accordance with embodiments of the present invention. It will be appreciated by those skilled in the art that the words during, while, and when as used herein are not exact terms that mean an action takes place instantly upon an initiating action but that there may be some small but reasonable delay, such as a propagation delay, between the reaction that is initiated by the initial action. The use of the words approximately, about, or substantially means that a value of an element has a parameter that is expected to be very close to a stated value or position. However, as is well known in the art there are always minor variances that prevent the values or positions from being exactly as stated. It is well established in the art that variances of up to about ten percent (10%) (and up to twenty percent (20%) for semiconductor doping concentrations) are regarded as reasonable variances from the ideal goal of exactly as described.

### DETAILED DESCRIPTION

Generally, the present invention provides a semiconductor component and a method for manufacturing the semiconductor component wherein the semiconductor component comprises a semiconductor material such as epitaxially grown silicon that has a 100% substitutional carbon concentration in the silicon, i.e., the carbon doped epitaxial layer comprises substitutional carbon. The epitaxial silicon may be grown on a silicon substrate, have a carbon concentration ranging from about 0.01% to about 49.99%, and may be referred to as a carbon doped epitaxial layer. A compound semiconductor material is grown on the carbon doped epitaxial layer. Because the carbon concentration is less that 50%, silicon carbide is not formed from the epitaxial layer. It should be noted that the carbon concentration of 2.5% corresponds to a carbon concentration of 1.25×10²¹ atoms/centimeter⁻³, i.e., 1.25×10²¹ cm⁻³.

In accordance with an embodiment, the carbon doping profile is a graded profile having a peak concentration near the surface of the carbon doped epitaxial layer and decreasing as the distance into the epitaxial layer from its surface increases. In an embodiment, the concentration decreases linearly.

In accordance with another embodiment, the carbon concentration decreases as the distance into the carbon doped epitaxial layer increases until a predetermined distance into the carbon doped epitaxial layer is reached at which point the carbon concentration remains substantially constant.

In accordance with another embodiment, the carbon doping profile is substantially constant from the surface of the carbon doped epitaxial layer until a predetermined distance into the carbon doped epitaxial is reached at which point the carbon concentration becomes substantially zero.

In accordance with another embodiment, the carbon doping profile is substantially constant with a first concentration in a first doped region that extends from the surface of the carbon doped epitaxial layer to a first predetermined distance into the carbon doped epitaxial layer. The carbon doping profile is substantially constant with a second carbon concentration in a second doped region that extends from the first doped region to a second predetermined distance into the carbon doped epitaxial layer, at which point the carbon concentration becomes substantially zero and forms a first carbon-free region. The carbon doping profile is substantially constant with a third carbon concentration in a third doped region that extends from the first carbon-free region to a third predetermined distance into the carbon doped epitaxial layer, at which point the carbon concentration becomes substantially zero and forms a second carbon-free region. The third doped region has a carbon concentration that is intermediate between the first doped region and the second doped region. A plurality of vertically spaced apart carbon doping regions may be formed in the carbon doped epitaxial layer.

In accordance with an embodiment, the carbon doping profile is a graded profile having a peak concentration near the surface of the carbon doped epitaxial layer and decreases as the distance into the carbon doped epitaxial layer from its surface increases. The carbon concentration may decrease linearly. In addition a graded carbon doping profile may be formed in the compound semiconductor material grown on the carbon doped epitaxial layer. In accordance with this embodiment, the surface of the carbon doped epitaxial layer may serve as an interface between the carbon doped epitaxial layer and the compound semiconductor material and the carbon doping profile is a graded profile having a peak concentration near the interface between the carbon doped epitaxial layer and the compound semiconductor material and decreases as the distance from the interface to the compound semiconductor material increases.

In accordance with another embodiment, the carbon concentration decreases as the distance into the carbon doped epitaxial layer from its surface increases until a predetermined distance into the carbon doped epitaxial layer is reached at which point the carbon concentration remains substantially constant and the carbon concentration decreases as the distance into the compound semiconductor material from the interface between the carbon doped epitaxial layer and the compound semiconductor material increases until a predetermined distance into the carbon doped epitaxial layer is reached at which point the carbon concentration remains substantially constant.

In accordance with another embodiment, the carbon doping profile is substantially constant from the surface of the carbon doped epitaxial layer until a predetermined distance into the carbon doped epitaxial is reached at which point the carbon concentration becomes substantially zero and the carbon doping profile is substantially constant from the interface between the carbon doped epitaxial layer and the compound semiconductor material until a predetermined distance into the compound semiconductor material is reached at which point the carbon concentration becomes substantially zero.

In accordance with another embodiment, carbon doped striations are formed in the carbon doped epitaxial layer and in the compound semiconductor material. The striations may have the same carbon concentration or they may have different carbon concentrations.

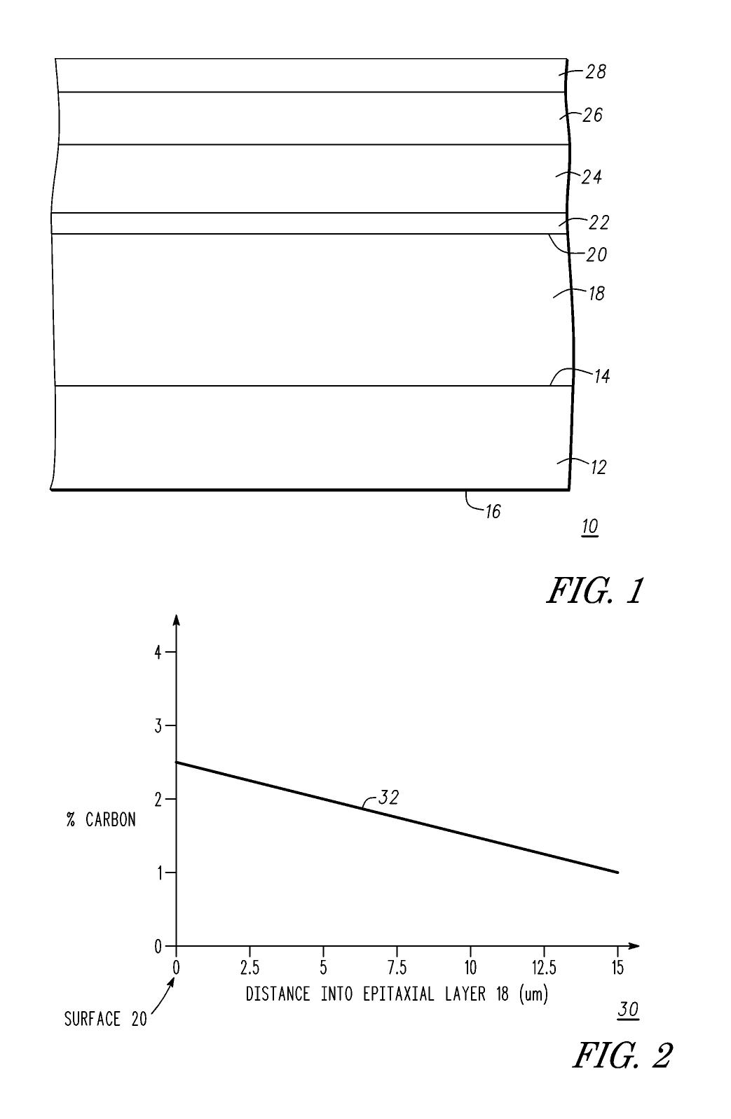

FIG. 1 is a cross-sectional view of a portion of a semiconductor component 10 such as, for example, a Light Emitting Diode (LED), a power switching device, a regulator, a protection circuit, a driver circuit, etc. during manufacture in accordance with an embodiment of the present invention. What is shown in FIG. 1 is a semiconductor substrate 12 having opposing surfaces 14 and 16. Surface 14 may be referred to as a front or top surface and surface 16 may be referred to as a bottom or back surface. Semiconductor substrate 12 may be of p-type conductivity, n-type conductivity, or it may be an intrinsic semiconductor material. In accordance with this embodiment, semiconductor substrate 12 is silicon doped with an impurity material of p-type conductivity and has a resistivity of at least about 5 Ohm-centimeters (Ω-cm).

In accordance with an embodiment, silicon substrate 12 is placed in a reaction chamber and an epitaxial layer of carbon-doped material 18 having a surface 20 is formed on silicon substrate 12. Epitaxial layer 18 is grown to have a 100% substitutional carbon concentration in the bulk silicon. Epitaxial layer 18 can be formed using Molecular Beam Epitaxy (MBE), Physical Vapor Deposition (PVD), or using chemical vapor deposition techniques such as, for example, a Metalorganic Chemical Vapor Deposition (MOCVD) technique, a Plasma-enhanced Chemical Vapor Deposition (PECVD) technique, a Low Pressure Chemical Vapor Deposition (LPCVD) technique, or the like. In accordance with an embodiment, epitaxial layer 18 may be grown by placing silicon substrate 12 in an ambient that includes silane and methylsilane and adjusting the temperature, growth rate of the epitaxial material, and thickness of the epitaxial material. For example, epitaxial layer 18 may be formed by MBE at room temperature and grown to have a thickness ranging from about one Angstrom (Å) to about one millimeter (mm). Alternatively, epitaxial layer 18 may be grown using MOCVD at a temperature that may range from about 25 degrees Celsius (° C.) to about 1,200 (° C.). The epitaxial deposition apparatus may be configured to form epitaxial layer 18 having a dopant profile in accordance with the desired operational specifications of a semiconductor device.

FIG. 2 illustrates a graded carbon doping profile 30. What is shown in FIG. 2 is a plot 32 in which a distance of zero into epitaxial layer 18 represents the concentration of carbon at surface 20. In an example shown in FIG. 2, the concentration of carbon at surface 20 is about 2.5%. It should be noted that a carbon concentration of 2.5% represents a concentration of about 1.25×10²¹ atoms per cubic centimeter (cm⁻³). Thus, a carbon concentration of 42.5% is about 1.7×10²² cm⁻³. Because the carbon doping is graded, the concentration of carbon decreases as the distance into epitaxial layer 18 from surface 20 increases. Thus, at 2.5 micrometers (μm), the concentration of carbon is about 2.33%; at 5 μm, the concentration of carbon is about 2.17%, at 7.5 μm, the concentration of carbon is about 2%, etc.

Referring again to FIG. 1, a nucleation layer 22 having a thickness ranging from about a mono-layer of carbon to about 100 μm is formed on epitaxial layer 18. By way of example, nucleation layer 22 is aluminum nitride. Other suitable materials for nucleation layer 22 include a combination of silicon and aluminum nitride, silicon carbide, aluminum gallium nitride, or the like.

A buffer layer 24 having a thickness ranging from about 0.1 μm to about 100 μm is formed on nucleation layer 22 at a temperature ranging from about 150° C. to about 1,500° C. In accordance with an embodiment, buffer layer 24 is a layer of III-N material. Suitable materials for buffer layer 24 include Group III-N materials such as, for example, aluminum nitride (AlN), gallium nitride (GaN), indium nitride (InN), aluminum gallium nitride (AlGaN), aluminum indium nitride (AlInN), aluminum indium gallium nitride (AlInGaN), indium gallium nitride (InGaN), or the like. Buffer layer 24 may be formed using MBE, PECVD, MOCVD, Metal Organic Vapor Phase Epitaxy (MOVPE), Remote Plasma Enhanced Chemical Vapor Deposition (RP-CVD), hydride vapor phase epitaxy (HVPE), liquid phase Epitaxy (LPE), Chloride Vapor Phase Epitaxy (Cl-VPE), or the like. It should be noted that buffer layer 24 may be comprised of a plurality of layers such as for example a plurality of MN layers, a plurality of GaN layers, or alternating stacked MN and GaN layers. Buffer layer 24 may be of p-type conductivity, n-type conductivity, or an intrinsic semiconductor material.

Still referring to FIG. 1, a channel layer 26 having a thickness ranging from about 0.1 μm to about 10 μm is formed on nucleation layer 22 using one or more techniques selected from the group of techniques including MBE, PECVD, MOCVD, MOVPE, RP-CVD, HVPE, LPE, Cl-VPE, or the like. By way of example, channel layer 26 is a GaN layer having a thickness ranging from about 0.5 μm to about 7.5 μm.

A strained layer 28 having a thickness ranging from about 10 nanometers (nm) to about 1,000 nm is formed on channel layer 26 using one or more techniques selected from the group of techniques including MBE, PECVD, MOCVD, MOVPE, RP-CVD, HVPE, LPE, Cl-VPE, or the like. By way of example, strained layer 28 is an AlGaN layer having a thickness ranging from about 20 nm to about 100 nm.

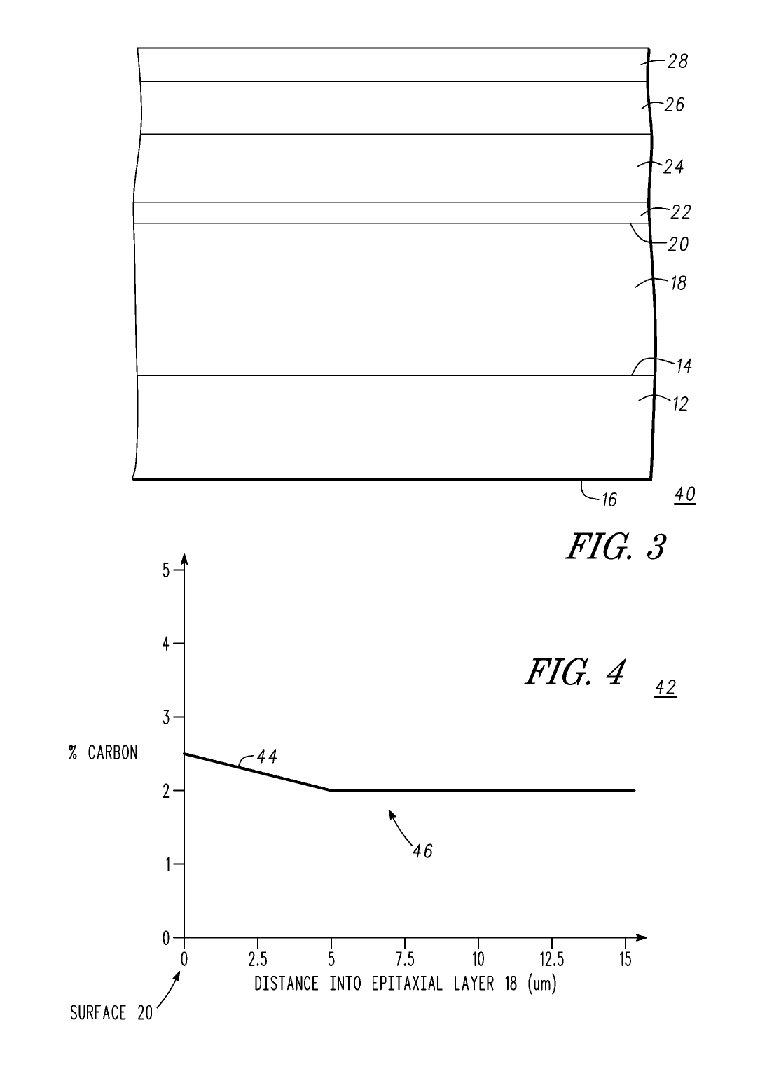

FIG. 3 illustrates a semiconductor component 40 that has a similar structure to semiconductor component 10; however, the carbon doping profile 42 in epitaxial layer 18 is different as illustrated in FIG. 4. More particularly, FIG. 4 illustrates that the carbon doping profile 42 has a graded portion 44 that linearly decreases from about a 2.5% carbon concentration to about a 2.25% carbon concentration from surface 20 to a depth of, for example, 3.75 μm, respectively, at which point the carbon dopant concentration becomes substantially constant. It should be noted that these numbers are merely exemplary numbers illustrating the graded portion 44 of doping profile 42 and the constant or flat portion 46 of doping profile 42. Thus, FIG. 4 shows that the carbon doping profile 42 has the highest carbon concentration at surface 20, i.e., zero distance into epitaxial layer 18, and decreases until a depth of about 3.75 μm into epitaxial layer 18 at which point the carbon dopant concentration remains substantially constant. The techniques for forming doping profile 42 may be similar to those for forming carbon doping profile 30 of FIG. 2.

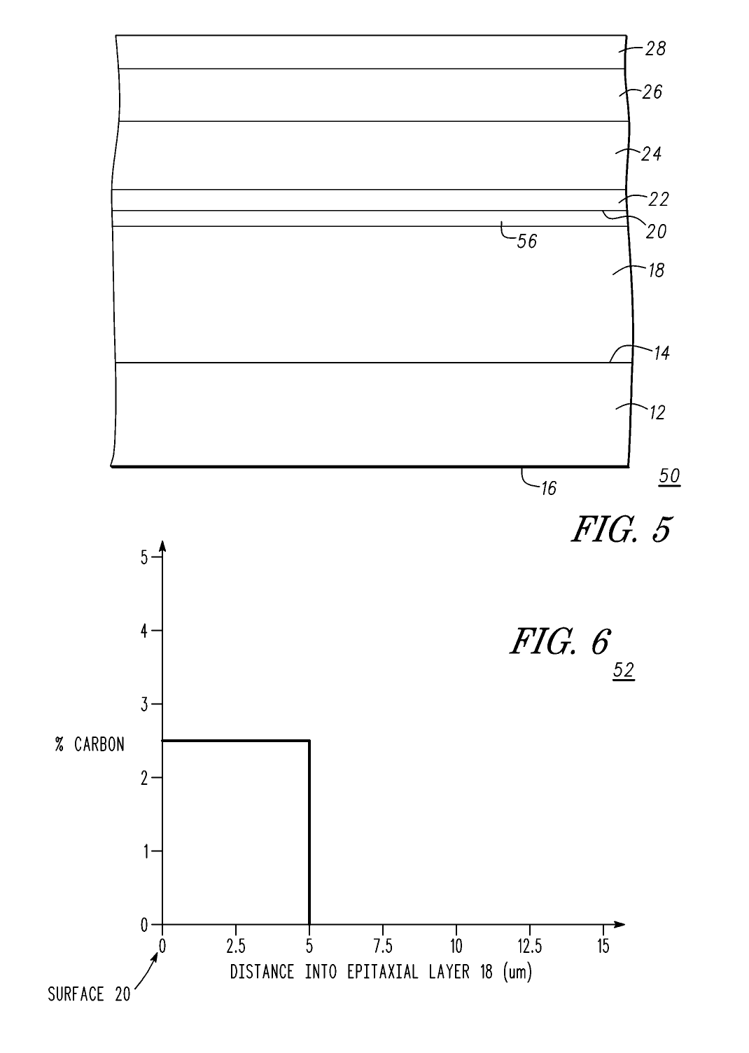

FIG. 5 illustrates a semiconductor component 50 that has a similar structure to semiconductor components 10 and 40; however, carbon doping profile 52 in epitaxial layer 18 is different as illustrated in FIG. 6. More particularly, FIG. 6 illustrates that carbon doping profile 52 is substantially constant or flat at about 4% until a distance of about 3.75 μm into epitaxial layer 18 at which point the carbon dopant concentration becomes substantially zero. It should be noted that these numbers are merely exemplary numbers illustrating the constant or flat nature 54 of doping profile 52. This constant carbon doping profile is also illustrated in FIG. 5 as doped region 56. The techniques for forming doping profile 42 may be similar to those for forming carbon doping profile 30 of FIG. 2 or carbon doping profile 42 of FIG. 4.

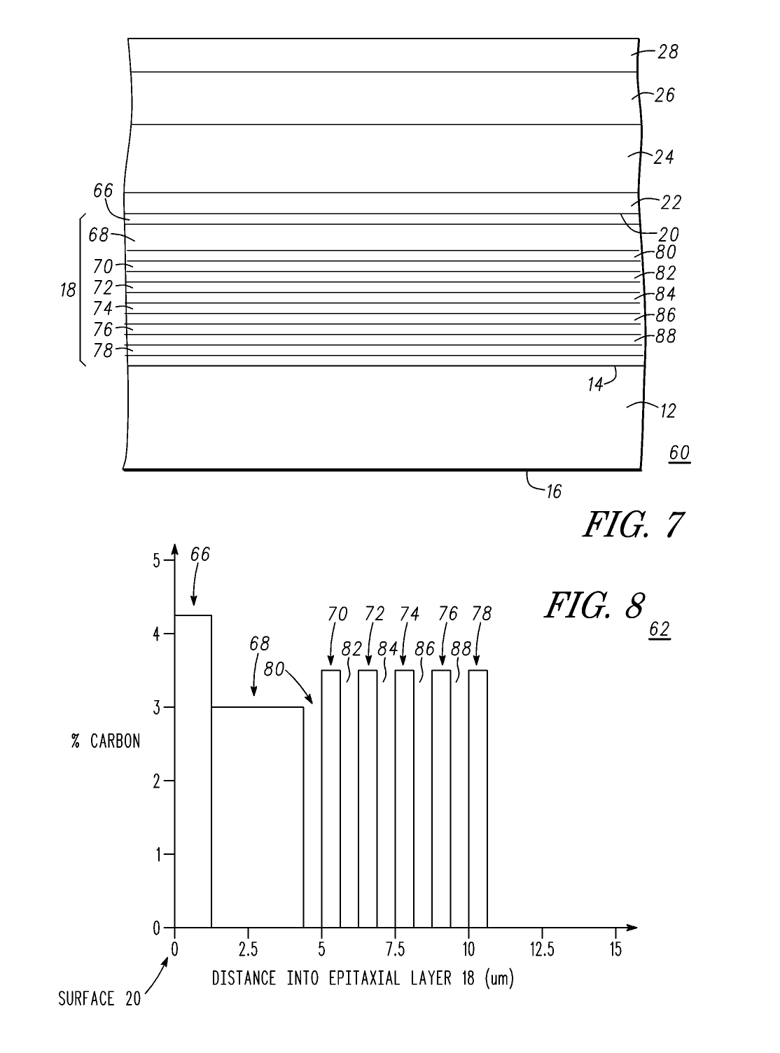

FIG. 7 illustrates a semiconductor component 60 that has a similar structure to semiconductor components 10, 40, and 50; however, the carbon doping profile 62 is different as illustrated in FIG. 8. More particularly, FIG. 8 illustrates that the carbon doping profile 62 in epitaxial layer 18 is substantially constant or flat at about 4.25% until a distance of about 1.25 μm into epitaxial layer 18 at which point the carbon dopant concentration becomes substantially constant or flat at about 3% until a distance of about 4.38 μm into epitaxial layer 18 at which point the carbon dopant concentration becomes substantially zero. The carbon dopant concentration remains substantially zero until a distance of about 5 μm into epitaxial layer 18 at which point the carbon dopant concentration is about 3.5%. From about 5 μm to about 5.63 μm into epitaxial layer 18 the carbon dopant concentration is about 3.5%. Similarly the carbon dopant concentration is about 3.5% from about 6.25 μm to about 6.88 μm into epitaxial layer 18, from about 7.5 μm to about 8.13 μm into epitaxial layer 18, from about 8.75 μm to about 9.38 μm into epitaxial layer 18, and from about 10 μm to about 10.63 μm into epitaxial layer 18. The carbon dopant concentration is substantially zero from about 5.63 μm to about 6.25 μm into epitaxial layer 18, from about 6.88 μm to about 7.5 μm into epitaxial layer 18, from about 8.13 μm to about 8.75 μm into epitaxial layer 18, from about 9.38 μm to about 10 μm into epitaxial layer 18, and from 10.63 μm into epitaxial layer 18. It should be noted that these numbers are merely exemplary numbers illustrating doping profile 62.

This constant carbon doping profile is also illustrated in FIG. 7 as doped regions 66, 68, 70, 72, 74, 76, and 78, where doped region 66 is the region from surface 20 to about 1.25 μm into epitaxial layer 18, doped region 68 is the region from about 1.25 μm to about 4.38 μm into epitaxial layer 18, doped region 70 is the region from about 5 μm to about 5.63 μm into epitaxial layer 18, doped region 72 is the region from about 6.25 μm to about 6.88 μm into epitaxial layer 18, doped region 74 is the region from about 7.5 μm to about 8.13 μm into epitaxial layer 18, doped region 76 is the region from about 8.75 μm to about 9.38 μm into epitaxial layer 18, and doped region 78 is the region from about 10 μm to about 10.63 μm into epitaxial layer 18. Region 80 is the region between doped region 68 and doped region 70 that has a carbon concentration of substantially 0%, region 82 is the region between doped region 70 and doped region 72 that has a carbon concentration of substantially 0%, region 84 is the region between doped region 72 and doped region 74 that has a carbon concentration of substantially 0%, region 86 is the region between doped region 74 and doped region 76 that has a carbon concentration of substantially 0%, and region 88 is the region between doped region 76 and doped region 78 that has a carbon concentration of substantially 0%. Thus, doped regions 70, 72, 74, 76, and 78 form striated regions.

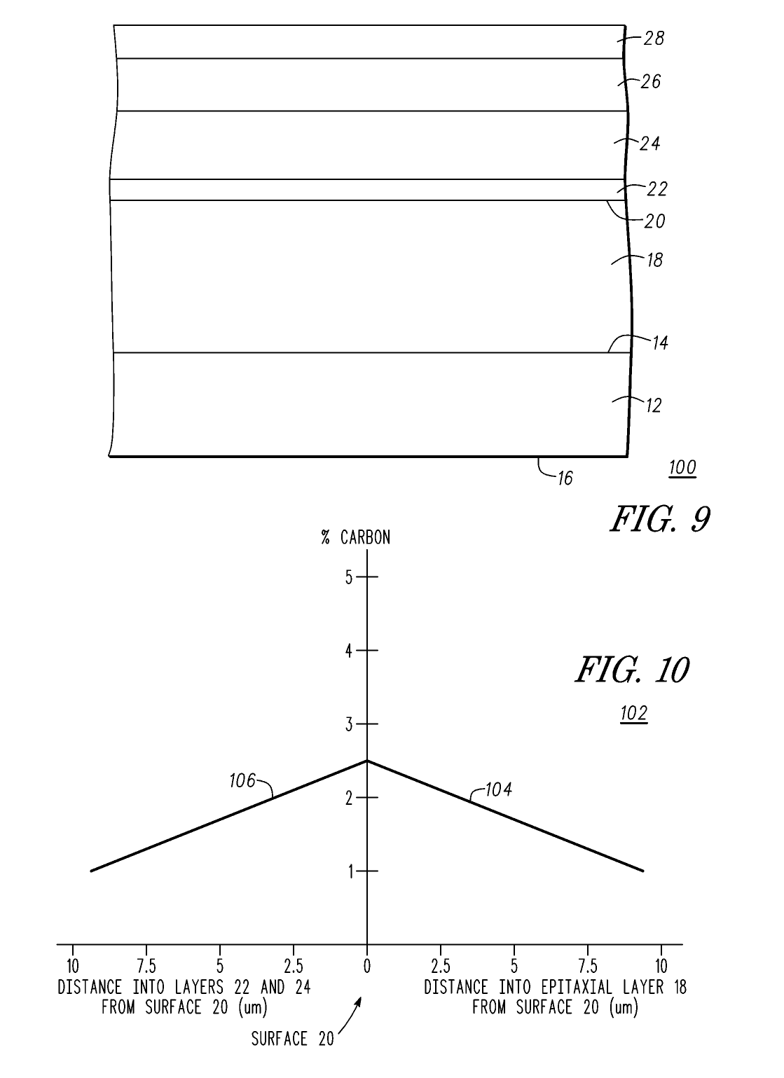

FIG. 9 illustrates a semiconductor component 100 that has a similar structure to semiconductor component 10; however, the carbon doping profile is different as illustrated in FIG. 10. More particularly, FIG. 10 is a graph 102 illustrating a graded carbon doping plot 104 that extends from surface 20 into epitaxial layer 18 and a graded carbon doping plot 106 that extends from surface 20 into at least nucleation layer 22 and may also extend into buffer layer 24. Surface 20 may be referred to as the interface between epitaxial layer 18 and nucleation layer 22 because it contacts nucleation layer 22. It should be noted that the portion of the abscissa identified as 0 micrometers represents surface or interface 20, wherein the portion of the abscissa extending to the right of surface 20 represents a distance into epitaxial layer 18 and the portion of the abscissa to the left of surface 20 represents a distance into at least nucleation layer 20 and may extend into buffer layer 24. What is shown in FIG. 10 is plot 102 in which a distance of zero into epitaxial layer 18 represents the concentration of carbon at surface 20. In an example shown in FIG. 10, the concentration of carbon at surface 20 is about 2.5%. It should be noted that a concentration of 2.5% represents a concentration of about 1.25×10²¹ cm⁻³. Because the carbon doping is graded, the concentration of carbon decreases as the distance into epitaxial layer 18 from surface 20 increases. Thus, at 2.5 μm, the concentration of carbon is about 2.33%; at about 5 μm the concentration of carbon is about 2.17%, at about 7.5 μm the concentration of carbon is about 2%, etc.

FIG. 10 includes plot 106 in which a distance of zero into nucleation layer 22 represents the concentration of carbon at surface 20. In an example shown in FIG. 10, the concentration of carbon at surface 20 is about 2.5%. It should be noted that a concentration of 2.5% represents a concentration of about 1.25×10²¹ cm⁻³. Because the carbon doping is graded, the concentration of carbon decreases as the distance into nucleation layer 22 from surface 20 increases. Thus, at 2.5 μm into nucleation layer 22 from surface 20 the concentration of carbon is about 2.33%; at 5 μm into nucleation layer 22 from surface 20 the concentration of carbon is about 2.17%, at about 7.5 μm into nucleation layer 22 from surface 20 the concentration of carbon is about 2%, etc. Thus, semiconductor component 100 comprises a carbon-doped silicon substrate and carbon-doped III-N buffer layers.

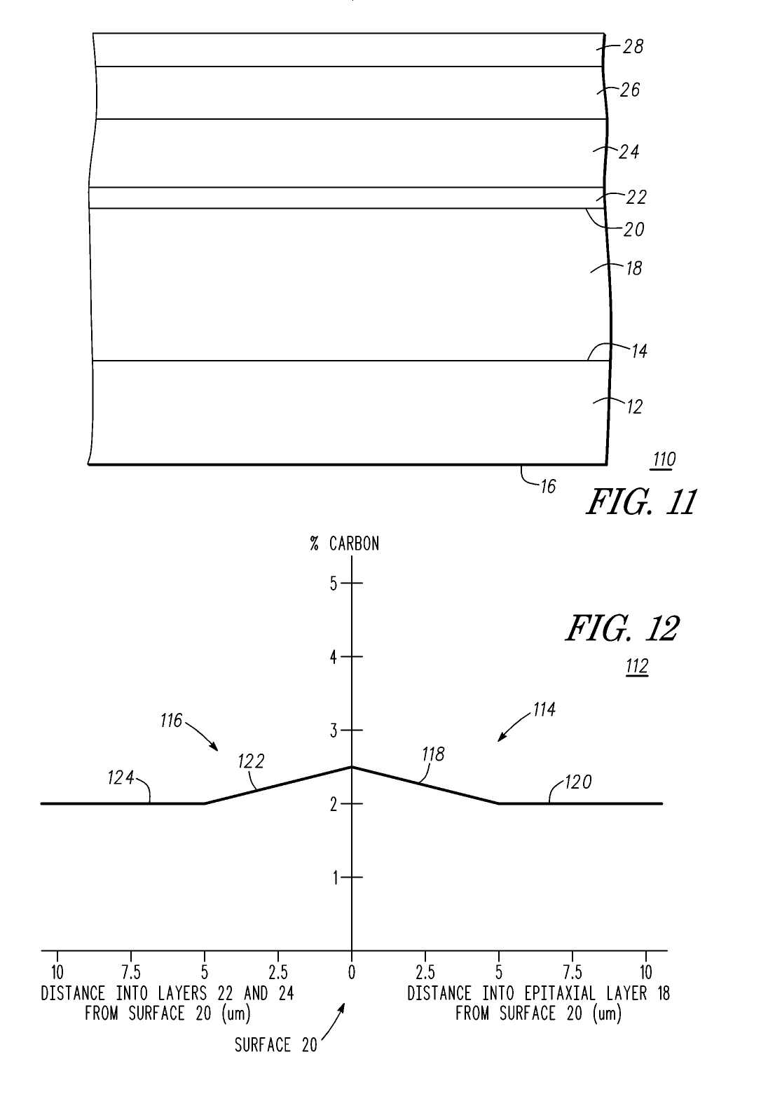

FIG. 11 illustrates a semiconductor component 110 that has a similar structure to semiconductor component 100; however, the carbon doping profile 112 is different as illustrated in FIG. 12. More particularly, FIG. 12 illustrates that the carbon doping profile 112 includes a profile 114 that extends from surface 20 into epitaxial layer 18 and a profile 116 that extends from surface 20 into at least nucleation layer 22 and may extend into buffer layer 24. Profile 114 has a graded portion 118 that linearly decreases from about 2.5% carbon concentration to about a 2.25% carbon concentration from surface 20 to a depth of, for example, 3.75 μm, in to epitaxial layer 18, respectively, at which point the carbon dopant concentration remains substantially constant. The portion of profile 114 that is substantially constant is identified by reference character 120. Profile 116 has a graded portion 122 that linearly decreases from about a 2.5% carbon concentration to about 2.25% carbon concentration from surface 20 to a distance of, for example, 3.75 μm, into buffer layer 24 from surface 20 at which point the carbon dopant concentration becomes substantially constant. The portion of profile 116 that is substantially constant is identified by reference character 124. Thus, semiconductor component 110 comprises a carbon-doped silicon substrate and carbon-doped III-N buffer layers.

It should be noted that these numbers are merely exemplary numbers illustrating the graded portion 118 of doping profile 114, the constant or flat portion 120 of doping profile 114, the graded portion 122 of doping profile 116, and the constant or flat portion 124 of doping profile 116. Thus, FIG. 12 shows that the carbon dopant concentration decreases as the distance into epitaxial layer 18 and nucleation layer 22 increases until a distance at which point the carbon dopant concentration becomes substantially constant. The techniques for forming doping profiles 114 and 116 may be similar to those for forming carbon doping profile 30 of FIG. 2.

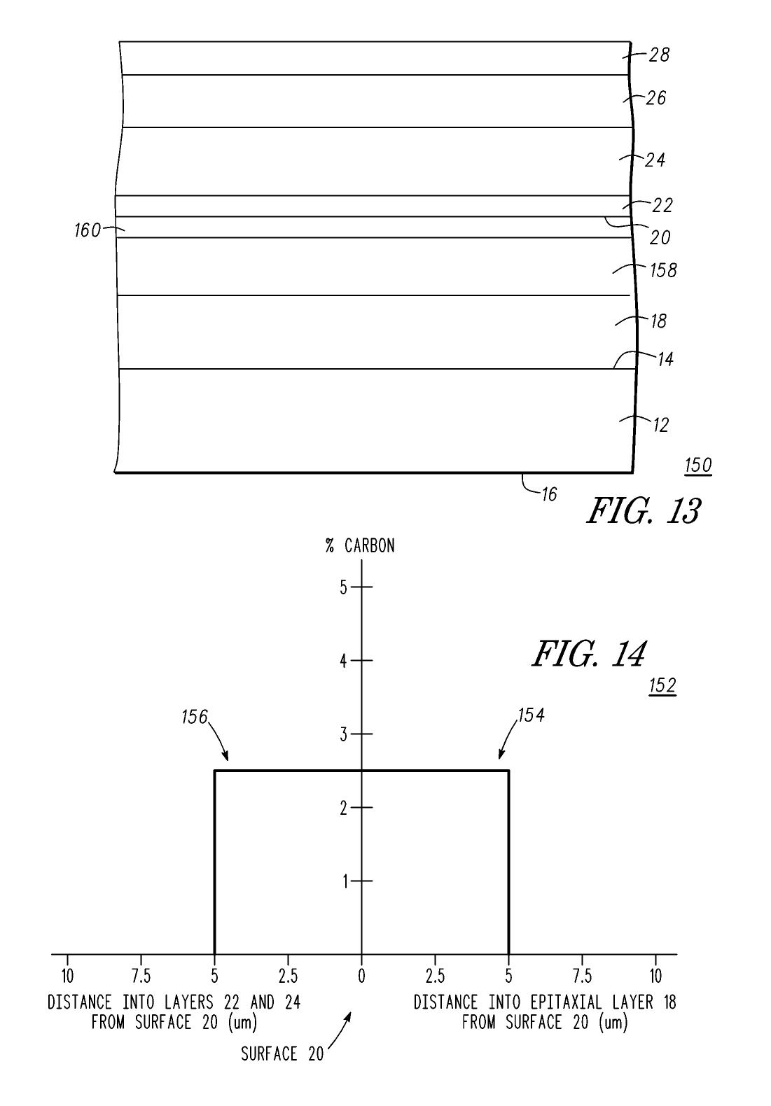

FIG. 13 illustrates a semiconductor component 150 that has a similar structure to semiconductor components 10 and 40; however, the carbon doping profile 152 is different as illustrated in FIG. 14. More particularly, FIG. 14 illustrates that the carbon doping profile 152 includes a portion 154 that is substantially constant or flat at about 40% until a distance of about 15 μm into epitaxial layer 18 at which point the carbon dopant concentration becomes substantially zero and a portion 156 that is substantially constant or flat at about 4% until a distance of about 3.75 μm into buffer layer 24 from surface or interface 20. It should be noted that these numbers are merely exemplary numbers illustrating the constant or flat portions 154 and 156 of doping profile 152. These constant carbon doping portions of carbon doping profile 152 are also illustrated in FIG. 13 as doped regions 158 and 160. Thus, semiconductor component 150 comprises a carbon-doped silicon substrate and carbon-doped III-N buffer layers.

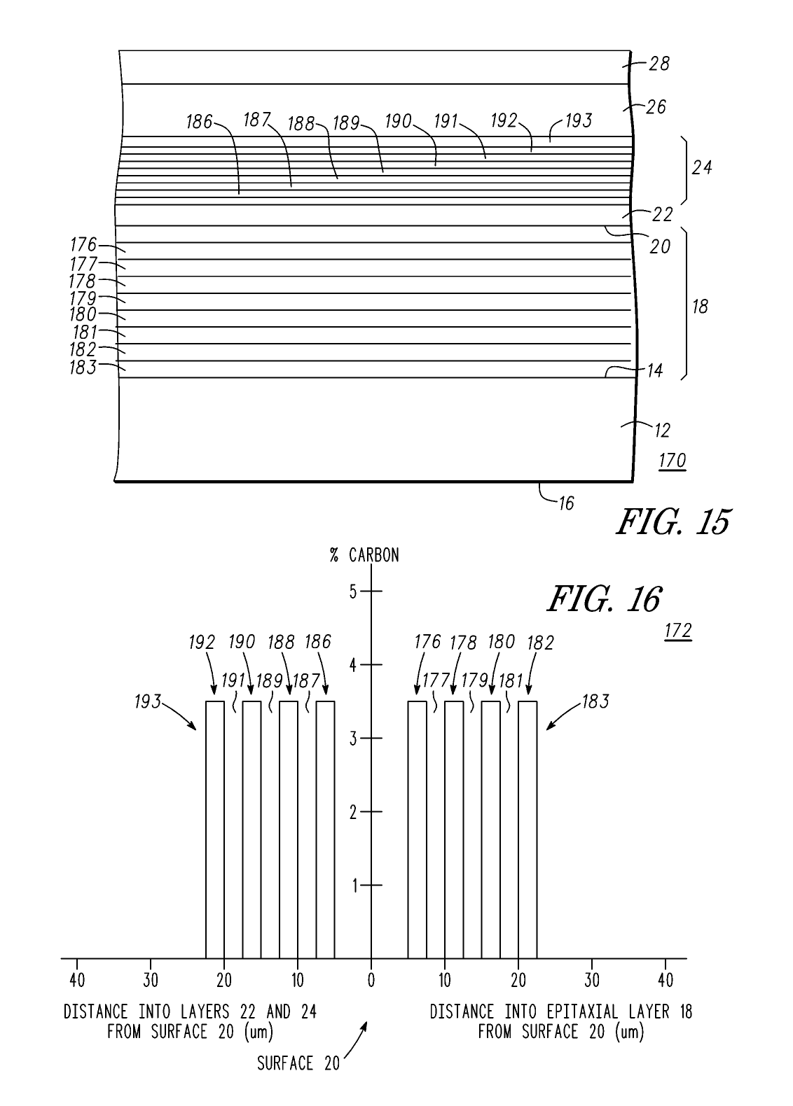

FIG. 15 illustrates a semiconductor component 170 that has a similar structure to semiconductor components 10, 40, and 50; however, the carbon doping profile 172 is different as illustrated in FIG. 16. More particularly, FIG. 16 illustrates that the carbon doping profile 172 is substantially 0% until a distance of about 5 μm into epitaxial layer 18 at which point the carbon dopant concentration becomes substantially constant or flat at about 3.5% until a distance of about 7.5 μm into epitaxial layer 18 at which point the carbon dopant concentration becomes substantially zero. The carbon dopant concentration remains substantially zero until a distance of about 10 μm into epitaxial layer 18 at which point the carbon dopant concentration is substantially constant at about 3.5% and remains substantially constant until a distance of about 12.5 μm into epitaxial layer 18. Similarly the carbon dopant concentration is about 3.5% from about 15 μm to about 17.5 μm into epitaxial layer 18 and from about 20 μm to about 22.5 μm into epitaxial layer 18. The carbon dopant concentration is substantially zero from about 7.5 μm to about 10 μm into epitaxial layer 18, from about 12.5 μm to about 15 μm into epitaxial layer 18, and from about 17.5 μm to about 20 μm into epitaxial layer 18. It should be noted that these numbers are merely exemplary numbers illustrating doping profile 172.

This constant carbon doping profile is also illustrated in FIG. 15 as doped regions 176, 178, 180, and 182, where doped region 176 is the region from about 5 μm to about 7.5 μm into epitaxial layer 18, doped region 178 is the region from about 10 μm to about 12.5 μm into epitaxial layer 18, doped region 180 is the region from about 15 μm to about 17.5 μm into epitaxial layer 18, and doped region 182 is the region from about 20 μm to about 22.5 μm into epitaxial layer 18. Region 177 is the region between doped region 176 and doped region 178 that has a carbon concentration of substantially 0%, region 179 is the region between doped region 178 and doped region 180 that has a carbon concentration of substantially 0%, region 181 is the region between doped region 180 and doped region 182 that has a carbon concentration of substantially 0%, and region 183 is the region in epitaxial layer that is below or further into epitaxial layer 18 from surface 20 and that has a carbon concentration of substantially 0%. Thus, doped regions 176, 178, 180, and 182 are striations forming a striated region.

In addition, carbon doping profile 172 is substantially 0% until a distance of about 5 μm into buffer layer 24 from surface or interface 20 at which point the carbon dopant concentration becomes substantially constant or flat at about 3.5% until a distance of about 7.5 μm into buffer layer 24 from surface or interface 20 at which point the carbon dopant concentration becomes substantially zero. The carbon dopant concentration remains substantially zero until a distance of about 10 μm into buffer layer 24 from surface or interface 20 at which point the carbon dopant concentration is about 3.5%. From about 10 μm to about 12.5 μm into buffer layer 24 from surface or interface 20 the carbon dopant concentration is about 3.5%. Similarly the carbon dopant concentration is about 3.5% from about 15 μm to about 17.5 μm into buffer layer 24 and from about 20 μm to about 22.5 μm into buffer layer 24 from surface or interface 20. The carbon dopant concentration is substantially zero from about 7.5 μm to about 10 μm into buffer layer 24, from about 12.5 μm to about 15 μm into buffer layer 24, and from about 17.5 μm to about 20 μm into buffer layer 24 from surface or interface 20. It should be noted that these numbers are merely exemplary numbers illustrating doping profile 172. This constant carbon doping profile is also illustrated in FIG. 15 as doped regions 186, 188, 190, and 192, where doped region 186 is the region from about 5 μm to about 7.5 μm into buffer layer 24 from surface or interface 20, doped region 188 is the region from about 10 μm to about 12.5 μm into buffer layer 24 from surface or interface 20, doped region 190 is the region from about 15 μm to about 17.5 μm into buffer layer 24 from surface or interface 20, and doped region 192 is the region from about 20 μm to about 22.5 μm into buffer layer 24 from surface or buffer layer 20. Region 187 is the region between doped region 186 and doped region 188 that has a carbon concentration of substantially 0%, region 189 is the region between doped region 188 and doped region 190 that has a carbon concentration of substantially 0%, region 191 is the region between doped region 190 and doped region 192 that has a carbon concentration of substantially 0%, and region 193 is the region in epitaxial layer that is above or further into buffer layer 24 from surface 20 and that has a carbon concentration of substantially 0%. Thus, doped regions 186, 188, 190, and 192 are striations forming a striated region and semiconductor component 170 comprises a carbon-doped silicon substrate and carbon-doped III-N buffer layers.

By now it should be appreciated that a semiconductor component that includes a carbon-doped silicon substrate and a method for manufacturing the semiconductor component have been provided. It should be noted that a carbon-doped silicon substrate may be comprised of a silicon substrate substitutionally doped with carbon or a silicon semiconductor substrate having an epitaxial layer formed thereon in which the epitaxial layer is substitutionally doped with carbon. Both of these materials may be referred to as a carbon-doped silicon substrate. In accordance with embodiments, the semiconductor component includes III-N material formed on a carbon-doped silicon substrate. Semiconductor components manufactured from a semiconductor material that includes a III-N semiconductor material formed on a carbon-doped silicon substrate increases that band gap of the semiconductor component which improves the breakdown voltage. In addition, carbon-doped silicon substrates have a reduced lattice mismatch which lowers wafer stress or strain and lowers the dislocation density; have increased wafer stiffness which reduces wafer bowing and warping; and have increased resistivity, thermal conductivity, and resistance to irradiation. Increasing the wafer stiffness reduces wafer breakage during wafer thinning. In addition to doping the silicon substrate with carbon, embodiments of semiconductor components that include carbon-doped III-N buffer layers provides current leakage control as an acceptor to III-N layers, allows thicker buffer layer growth and reduced dislocation density.

Although certain preferred embodiments and methods have been disclosed herein, it will be apparent from the foregoing disclosure to those skilled in the art that variations and modifications of such embodiments and methods may be made without departing from the spirit and scope of the invention. It is intended that the invention shall be limited only to the extent required by the appended claims and the rules and principles of applicable law.

What is claimed is:

1. A method for manufacturing a semiconductor component, comprising:
providing a semiconductor material having a surface;
forming an epitaxial layer of carbon doped semiconductor material on the semiconductor substrate, the epitaxial layer having a surface;
forming a nucleation layer on the epitaxial layer; and
forming a layer of III-nitride material on the nucleation layer.

2. The method of claim 1, wherein forming the epitaxial layer comprises epitaxially growing carbon doped silicon as the epitaxial layer, wherein the epitaxially grown carbon doped silicon comprises substitutional carbon.

3. The method of claim 2, wherein forming the epitaxial layer comprises epitaxially growing carbon doped silicon having a 100% substitutional carbon concentration.

4. The method of claim 1, wherein forming the epitaxial layer comprises epitaxially growing carbon doped silicon having a carbon concentration ranging from 0.01% to 49.99%.

5. The method of claim 1, wherein forming the epitaxial layer of carbon doped semiconductor material on the semiconductor substrate includes doping with epitaxial layer with carbon having a graded concentration profile.

6. The method of claim 5, wherein the graded concentration profile of the carbon extends a first distance into the epitaxial layer from the surface of the epitaxial layer.

7. The method of claim 1, wherein forming the epitaxial layer of carbon doped semiconductor material on the semiconductor substrate includes doping with epitaxial layer with carbon having a spiked concentration profile adjacent the surface of the epitaxial layer.

8. The method of claim 1, wherein forming the epitaxial layer of carbon doped semiconductor material on the semiconductor substrate includes doping with epitaxial layer with carbon having a spiked concentration profile adjacent an interface between the epitaxial layer and the nucleation layer.

9. The method of claim 1, wherein forming the epitaxial layer of carbon doped semiconductor material on the semiconductor substrate includes doping the epitaxial layer with carbon having a concentration profile configured as a plurality of doping layers.

10. A method for manufacturing a semiconductor device, comprising:
providing a semiconductor material;
forming a carbon doped epitaxial layer on the semiconductor material, the carbon doped epitaxial layer having a carbon doping profile;
forming a nucleation layer on the carbon doped epitaxial layer; and
forming a buffer layer on the nucleation layer.

11. The method of claim 10, wherein forming the nucleation layer comprises forming an aluminum nitride layer on the carbon doped epitaxial layer.

12. The method of claim 10, further including forming the carbon doped epitaxial layer to have a portion with a uniform carbon doping profile.

13. The method of claim 10, further including forming the carbon doped epitaxial layer to have a carbon doping profile that includes a graded portion and a uniform portion.

14. The method of claim 10, further including forming the carbon doped epitaxial layer to have a carbon doping profile that includes a plurality of dopant layers.

15. The method of claim 10, wherein forming the nucleation layer comprises forming a carbon doped nucleation layer.

16. A semiconductor component, comprising:
a silicon semiconductor substrate of a first conductivity type;
a carbon doped epitaxial layer on the silicon semiconductor substrate;
a buffer layer over the carbon doped buffer layer; and
a channel layer on the buffer layer.

17. The semiconductor component of claim 16, wherein the carbon doped buffer layer has an impurity material profile selected from the group of impurity material profiles comprising constant, graded, a constant portion and a graded portion, and striated.

18. The semiconductor component of claim 16, further including a nucleation layer between the carbon doped epitaxial layer and the buffer layer.

19. The semiconductor component of claim 16, wherein
the nucleation layer comprises aluminum nitride;
the buffer layer comprises a III-nitride material; and
the channel layer comprises gallium nitride.

20. The semiconductor component of claim 16, further including a strained layer on the channel layer, the strained layer comprising aluminum gallium nitride.
